(19) United States
(12) Patent Application Publication
(10) Pub. No.: US 2016/0248406 A1
(43) Pub. Date: Aug. 25, 2016

(54) SEMICONDUCTOR DEVICE

(71) Applicant: Kabushiki Kaisha Toshiba, Tokyo (JP)

(72) Inventor: Hirokazu Kadowaki, Fujisawa Kanagawa (JP)

(21) Appl. No.: 14/845,665

(22) Filed: Sep. 4, 2015

(30) Foreign Application Priority Data
Feb. 23, 2015 (JP) 2015-033250

(51) Int. Cl. H03K 3/3565; H03K 5/24; H03K 3/012

(52) U.S. Cl. CPC H03K 3/3565; H03K 3/012; H03K 5/2481

(57) ABSTRACT

A semiconductor device according to an embodiment includes a differential circuit including a first current-path receiving a first voltage and a second current-path receiving a second voltage. A first mirror circuit can cause a current obtained by multiplying a current flowing through the first current-path by a first mirror ratio to flow through a third current-path. A second mirror circuit can cause a current obtained by multiplying a current flowing through the second current-path by a second mirror ratio to flow through a fourth current-path. A third mirror circuit can cause a current obtained by multiplying a current flowing through the third current-path by a third mirror ratio to flow through the fourth current-path. A first circuit changes any one of the first to third mirror ratios according to a logic level of data output from an output part that is connected to the fourth current-path.

### CROSS REFERENCE TO RELATED APPLICATIONS

This application is based upon and claims the benefit of priority from the prior Japanese Patent Application No. 2015-033250, filed on Feb. 23, 2015, the entire contents of which are incorporated herein by reference.

### FIELD

The embodiments of the present invention relate to a semiconductor device.

### BACKGROUND

A semiconductor device used for a sensor or the like sometimes includes a comparator that compares a setting value and a measurement value with each other. The comparator compares the setting value and the measurement value with each other and inverts the logic level of an output when the measurement value exceeds the setting value or when the measurement value falls below the setting value. However, a comparator that does not have hysteresis characteristics frequently inverts the logic level of an output when the measurement value rises and falls near the setting value. In this case, the operation of a device controlled based on the output of the comparator is destabilized. To address this problem, the comparator is designed to have the hysteresis characteristics in some cases.

To set the hysteresis characteristics of the comparator having the hysteresis characteristics, a resistive element is conventionally used. When the hysteresis characteristics are set using a resistive element, the comparator divides a certain reference voltage with the resistive element to generate a setting value (a voltage). Therefore, the setting value is lower than the reference voltage and the setting value cannot be set at the reference voltage itself. In this case, the ranges of the setting value and an output voltage of the comparator become narrow.

To meet the demand for low power consumption, the resistance value of the resistive element for the hysteresis characteristics is set to be large in some cases. In such cases, the layout area of the resistive element is increased and the proportion of the area of the resistive element in a semiconductor chip becomes large. Furthermore, when the resistance value of the resistive element is large, the RC time constant between the resistive element and the parasitic capacitance of a transistor connected to the resistive element is increased, which causes a problem of a reduced operation speed of the comparator.

### BRIEF DESCRIPTION OF THE DRAWINGS

FIG. 1 is a circuit diagram showing an example of a configuration of a comparator 1 according to a first embodiment;

FIG. 2 is a graph showing a relation between the input voltage Vin and the output voltage Vout of the comparator 1;

FIG. 3 is a circuit diagram showing an example of a configuration of a comparator 2 according to a second embodiment;

FIG. 4 is a circuit diagram showing an example of a configuration of a comparator 3 according to a third embodiment;

FIG. 5 is a circuit diagram showing an example of a configuration of a comparator 4 according to a fourth embodiment;

FIG. 6 is a circuit diagram showing an example of a configuration of a comparator 5 according to a fifth embodiment; and

FIG. 7 is a circuit diagram showing an example of a configuration of a comparator 6 according to a sixth embodiment.

### DETAILED DESCRIPTION

Embodiments will now be explained with reference to the accompanying drawings. The present invention is not limited to the embodiments.

A semiconductor device according to an embodiment comprises a differential circuit comprising a first current path receiving a first voltage and a second current path receiving a second voltage. A first mirror circuit is capable of causing a current obtained by multiplying a current flowing through the first current path by a first mirror ratio to flow through a third current path. A second mirror circuit is capable of causing a current obtained by multiplying a current flowing through the second current path by a second mirror ratio to flow through a fourth current path. A third mirror circuit is capable of causing a current obtained by multiplying a current flowing through the third current path by a third mirror ratio to flow through the fourth current path. A first circuit changes any one of the first to third mirror ratios according to a logic level of data output from an output part that is connected to the fourth current path.

### First Embodiment

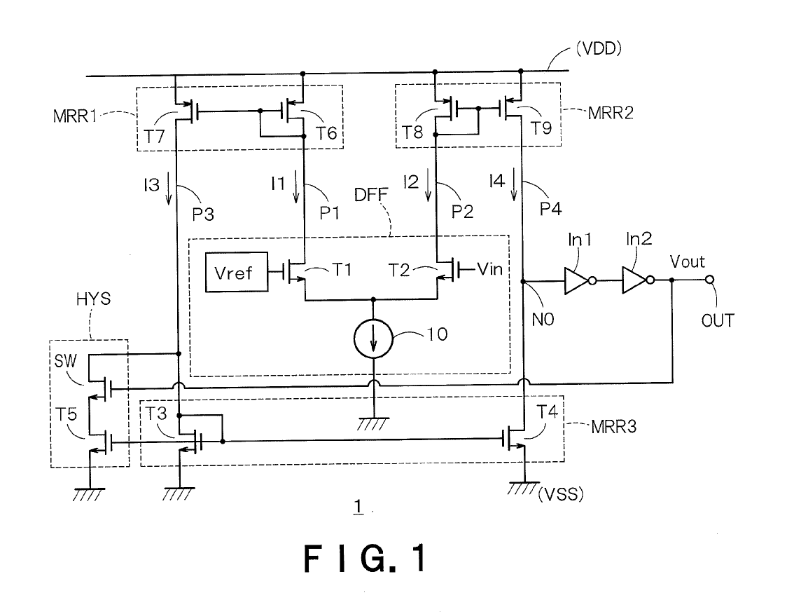

FIG. 1 is a circuit diagram showing an example of a configuration of a comparator 1 according to a first embodiment. The comparator 1 is a semiconductor device that receives an input voltage Vin and a reference voltage Vref as inputs and that outputs a result of comparison between the input voltage Vin and the reference voltage Vref from an output part OUT.

The comparator 1 includes a differential amplification circuit (differential circuit) DFF, mirror circuits MRR1, MRR2, and MRR3, a hysteresis circuit HYS, and inverters In1 and In2.

The differential amplification circuit DFF includes a first transistor T1, a second transistor T2, and a current source 10. The first transistor T1 is, for example, an N-MISFET (Metal Insulation Semiconductor Field Effect Transistor). The first transistor T1 is connected between a sixth transistor T6 and the current source 10 and is provided on a first current path P1. A gate of the first transistor T1 receives the reference voltage Vref to be used as a reference for the comparison. The second transistor T2 is, for example, an N-MISFET. The second transistor T2 is connected between an eighth transistor T8 and the current source 10 and is provided on a second current path P2. A gate of the second transistor T2 receives the input voltage Vin being a target for the comparison.

The current source 10 is connected to the first and second current paths P1 and P2 in common and causes a constant current to flow through the first and second current paths P1 and P2. The current source 10 causes a weak current to flow to operate the first and second transistors T1 and T2 in a weak inversion region.

The first mirror circuit MRR1 includes the sixth transistor T6 and a seventh transistor T7 and causes a current I3 corresponding to a current I1 flowing through the first current path P1 to flow through a third current path P3. The sixth transistor T6 is, for example, a P-MISFET and is connected between a first power supply (a high-level voltage source) VDD and the first transistor T1. The seventh transistor T7 is, for example, a P-MISFET and is connected between the first power supply VDD and a third transistor T3. Gates of the sixth and seventh transistors T6 and T7 are connected to the first current path P1 in common. The first mirror circuit MRR1 causes the current I3 proportional to the current I1 flowing through the first current path P1 to flow through the third current path P3 based on a ratio (a size ratio) between the size (the channel width (W)/the channel length (L)) of the sixth transistor T6 and the size (the channel width (W)/the channel length (L)) of the seventh transistor T7.

The second mirror circuit MRR2 includes the eighth transistor T8 and a ninth transistor T9 and causes a current I4 corresponding to a current I2 flowing through the second current path P2 to flow through a fourth current path P4. The eighth transistor T8 is, for example, a P-MISFET and is connected between the first power supply VDD and the second transistor T2. The ninth transistor T9 is, for example, a P-MISFET and is connected between the first power supply VDD and a fourth transistor T4. Gates of the eighth and ninth transistors T8 and T9 are connected to the second current path P2 in common. The second mirror circuit MRR2 attempts to cause the current I4 proportional to the current I2 flowing through the second current path P2 to flow through the fourth current path P4 based on a size ratio between the eighth transistor T8 and the ninth transistor T9. The third mirror circuit MRR3 includes the third transistor T3 and the fourth transistor T4 and causes the current I4 corresponding to the current I3 flowing through the third current path P3 to flow through the fourth current path P4. The third transistor T3 is, for example, an N-MISFET. The third transistor T3 is connected between the seventh transistor T7 and a second power supply (a low-level voltage source) VSS (a ground voltage, for example) and is provided on the third current path P3. The fourth transistor T4 is, for example, an N-MIS FET. The fourth transistor T4 is connected between the ninth transistor T9 and the second power supply VSS and is provided on the fourth current path P4. Gates of the third and fourth transistors T3 and T4 are connected to the third current path P3 in common. When a fifth transistor T5 (which will be explained later) is disconnected from the third current path P3, the third mirror circuit MRR3 attempts to cause the current I4 proportional to the current I3 flowing through the third current path P3 to flow through the fourth current path P4 based on a size ratio between the third transistor T3 and the fourth transistor T4. The current I4 in the fourth current path P4 hardly flows when a node N0 is in a steady state of being at logic high or logic low and flows when the node N0 is inverted between logic high and logic low.

This is because a conduction state of the fourth transistor T4 and a conduction state of the ninth transistor T9 are complementary with each other and are reversed when the logic level of the output part OUT is inverted.

The hysteresis circuit HYS as a first circuit includes the fifth transistor T5 and a switching element SW. The fifth transistor T5 is, for example, an N-MISFET. One end of the fifth transistor T5 is connected to the third current path P3 via the switching element SW and the other end thereof is connected to the second power supply VSS. A gate of the fifth transistor T5 is connected together with the gates of the third and fourth transistors T3 and T4 to the third current path P3 in common. Accordingly, when the switching element SW is in a conduction state, the fifth transistor T5 is connected in parallel to the third transistor T3. In this example, the conduction state is a state that enables a current to flow regardless of whether the current is actually caused to flow. In this case, the size (W5/L5) of the fifth transistor T5 is added to the size (W3/L3) of the third transistor T3. That is, it can be considered that the size of the third transistor T3 is substantially increased. On the other hand, when the switching element SW is in a non-conduction state, the one end of the fifth transistor T5 is disconnected from the third transistor T3 and the third current path P3. In this case, the size of the fifth transistor T5 is not added to the size of the third transistor T3. Therefore, the size of the third transistor T3 remains relatively small. It is assumed here that the channel widths of the third to fifth transistors T3 to T5 are W3 to W5 and the channel lengths thereof are L3 to L5, respectively.

The switching element SW is, for example, an N-MISFET and is connected between the third current path P3 and the fifth transistor T5. A gate of the switching element SW is connected to the output part OUT. Accordingly, the switching element SW is brought to the conduction state or the non-conduction state according to a logic level of the output part OUT. For example, in the first embodiment, the switching element SW is brought to the conduction state when the output part OUT is at logic high and is brought to the non-conduction state when the output part OUT is at logic low.

The fifth transistor T5 is connected in parallel to the third transistor T3 or disconnected from the third transistor T3 by the switching element SW that is brought to the conduction state or the non-conduction state in the above manner according to a logic level of the output part OUT. Accordingly, the size of the fifth transistor T5 is added or not added to the size of the third transistor T3 according to a logic level of the output part OUT. That is, the hysteresis circuit HYS can substantially change the size of the third transistor T3 according to a logic level of the output part OUT. This enables the comparator 1 to provide hysteresis characteristics in a relation between the input voltage Vin and an output voltage Vout as will be explained later. Alternatively, the switching element SW can be connected between the fifth transistor T5 and the second power supply VSS. That is, it suffices to connect the switching element SW in series with the fifth transistor T5.

The output part OUT is connected to the fourth current path P4 via the inverters In1 and In2. The output part OUT thereby outputs a logic level corresponding to a voltage level of the fourth current path P4.

An operation of the comparator 1 according to the first embodiment is explained next.

First, when the input voltage Vin is lower than the reference voltage Vref, the first transistor T1 is brought to the conduction state and the second transistor T2 is brought to the non-conduction state. Accordingly, the current I1 flows through the first current path P1 and the first mirror circuit MRR1 causes the current I3 corresponding to the current I1 to flow through the third current path P3. Therefore, the gates of the third to fifth transistors T3 to T5 become at a high-level voltage and the third to fifth transistors T3 to T5 are brought to the conduction state. At that time, the mirror ratio (I4/I3) of the third mirror circuit MRR3 is a ratio ((W4/L4)/(W3/L3)) between the size (W4/L4) of the fourth transistor T4 and the size (W3/L3) of the third transistor T3. Meanwhile, no current flows through the second current path P2 and the second mirror circuit MRR2 does not cause a current to flow from the first power supply VDD to the fourth current path P4. Therefore, the node N0 of the fourth current path P4 becomes at a low-level voltage and the voltage Vout also becomes a low-level voltage. That is, the output part OUT outputs logic low.

Because the switching element SW is brought to the non-conduction state when the output part OUT is at logic low, the fifth transistor T5 is electrically disconnected from the third current path P3 and the third transistor T3 and thus does not cause a current to flow through. Therefore, at that time, the size of the fifth transistor T5 is not added to the size of the third transistor T3.

### (Case 1: When Input Voltage Vin Exceeds Reference Voltage Vref)

Next, when the input voltage Vin increases and the input voltage Vin exceeds the reference voltage Vref, the second transistor T2 is brought to the conduction state and the first transistor T1 is brought to the non-conduction state. Accordingly, the current I2 flows through the second current path P2 and the second mirror circuit MRR2 attempts to cause a current corresponding to the current I2 to flow through the fourth current path P4. Meanwhile, no current flows through the first current path P1 and the first mirror circuit MRR1 does not cause a current to flow from the first power supply VDD to the third current path P3. Therefore, the gates of the third to fifth transistors T3 to T5 become at a low-level voltage and the third to fifth transistors T3 to T5 are brought to the non-conduction state. The node N0 of the fourth current path P4 thereby becomes at a high-level voltage and the voltage Vout also becomes a high-level voltage. That is, the output part OUT outputs logic high.

Because the switching element SW is brought to the conduction state when the output part OUT becomes at logic high, the fifth transistor T5 is connected in parallel to the third transistor T3 and can cause a current to flow together with the third transistor T3. Therefore, at that time, the size of the fifth transistor T5 is added to the size of the third transistor T3. That is, it can be considered that a substantial size of the third transistor T3 is increased by the size of the fifth transistor T5.

### (Case 2: When Input Voltage Vin Falls Below Reference Voltage Vref)

A case where the input voltage Vin lowers to fall below the reference voltage Vref is considered next. When the logic level of the output part OUT is high, the switching element SW is brought to the conduction state and thus the fifth transistor T5 is connected in parallel to the third transistor T3. In this case, the size of the fifth transistor T5 is added to the size of the third transistor T3. Therefore, the mirror ratio (I4/I3) of the third mirror circuit MRR3 is a ratio ((W4/L4)/(W3/L3)+(W5/L5)) between the total size of the third and fifth transistors T3 and T5 and the size of the fourth transistor T4. Therefore, the mirror ratio of the third mirror circuit MRR3 at a time when the switching element SW is in the conduction state (the case 2) is smaller than that of the third mirror circuit MRR3 at a time when the switching element SW is in the non-conduction state (the case 1). That is, a current flowing in the fourth transistor T4 in the case 2 is smaller than that flowing in the fourth transistor T4 in the case 1. In this example, when the logic level of the output part OUT is inverted, the conduction state of the fourth transistor T4 and the conduction state of the ninth transistor T9 are switched. A current value flowing in the fourth transistor T4 and a current value flowing in the ninth transistor T9 at the switching are almost equal to each other. Therefore, it is considered that the logic level of the output part OUT is inverted when the current value flowing in the fourth transistor T4 and the current value flowing in the ninth transistor T9 are almost equal to each other.

As described above, the current flowing in the fourth transistor T4 in the case 2 is smaller than that flowing in the fourth transistor T4 in the case 1. Therefore, when the logic level of the output part OUT is inverted in the case 2, the current flowing in the ninth transistor T9, which is to be equal to the current flowing in the fourth transistor T4, also naturally becomes smaller. That is, the current flowing in the ninth transistor T9 when the logic level of the output part OUT is inverted is smaller in the case 2 than in the case 1. Because the current flowing in the ninth transistor T9 depends on the current flowing in the eighth transistor T8, the current I2 flowing in the eighth transistor T8 when the logic level of the output part OUT is inverted is also smaller in the case 2 than in the case 1. That is, in the case 2, the logic value of the output part OUT is inverted when the current I2 becomes smaller. This means that the output part OUT is inverted when the input voltage Vin falls below a voltage (a second reference voltage Vref-Vhys) that is lower than the reference voltage Vref. As a result, the comparator 1 according to the first embodiment has hysteresis characteristics.

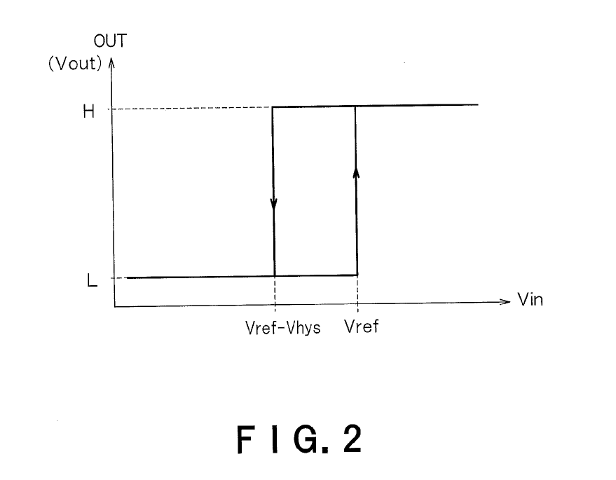

FIG. 2 is a graph showing a relation between the input voltage Vin and the output voltage Vout of the comparator 1. When the input voltage Vin is lower than the reference voltage Vref, the output part OUT is at logic low. Because the fifth transistor T5 is electrically disconnected from the third current path P3 at that time, the mirror ratio of the third mirror circuit MRR3 is increased and the fourth transistor T4 causes a relatively large current to flow in proportion to a current value of the third transistor T3. When the input voltage Vin increases to exceed the reference voltage Vref, the second transistor T2 is brought to the conduction state and the output part OUT is inverted from logic low to logic high.

Because the output part OUT becomes at logic high, the fifth transistor T5 is connected in parallel to the third transistor T3. Therefore, the mirror ratio of the third mirror circuit MRR3 is decreased and thus a current value that is enabled to flow in the fourth transistor T4 becomes smaller. Therefore, the input voltage Vin at the time of inversion of the output part OUT from logic high to logic low becomes the second reference voltage Vref-Vhys, which is lower than the reference voltage Vref, as described above. Accordingly, the logic level of the output part OUT is not inverted even when the input voltage Vin lowers to fall below the reference voltage Vref. When the input voltage Vin lowers to the second reference voltage Vref-Vhys, the logic level of the output part OUT is inverted from logic high to logic low. This brings the switching element SW to the non-conduction state and the fifth transistor T5 is electrically disconnected from the third current path P3. Therefore, the comparator 1 returns to a state before the input voltage Vin exceeds the reference voltage Vref in the case 1. As described above, the input voltage Vin at the time of switching of the output part OUT from logic low to logic high and the input voltage Vin at the time of switching of the output part OUT from logic high to logic low are different from each other and a voltage difference thereof is Vhys. The voltage difference Vhys is hereinafter referred to also as “hysteresis voltage”.

In the first embodiment, the current source 10 causes a weak constant current (a tail current) to flow in the first transistor T1 and/or the second transistor T2 to operate the first transistor T1 and the second transistor T2 in a weak inversion region as described above. In this case, the hysteresis voltage Vhys of the comparator 1 can be set as shown by an expression 1.

$$Vhys = n \cdot Vt \cdot ln α \\ where \\ \frac{1}{n} = \frac{Cox}{Cox + Cdep} \qquad ( Expression 1 )$$

(Typically, 1/n is equal to or smaller than 0.7)
Cox is the thickness of gate oxide films of the transistors T1 to T9 and is a constant determined by a manufacturing process.
Cdep is the capacitance of depletion layers generated just under the gate oxide films of the transistors T1 to T9 and is a constant determined by a manufacturing process.
Vt is a thermal voltage (0.026 volt at normal temperatures).
α is the ratio between (the size of the transistor T3+the size of the transistor T5) and the size of the transistor T4 and is, that is, ((W3/L3)+(W5/L5))/(W4/L4).

The expression 1 is explained. When the first transistor T1 and the second transistor T2 operate in a weak inversion region, the current I4 flowing in the fourth transistor T4 and the current I9 flowing in the ninth transistor T9 are represented by the following expressions 2 and 3, respectively. It is assumed that the sizes of the first transistor T1 and the second transistor T2 are the same.

$$\begin{matrix}I 4 = \frac{1}{α} \cdot I 1 = \frac{1}{α} \cdot Io \cdot \frac{W 1}{L 1} \cdot {ɛ}^{( \frac{Vg / n - Vs}{Vt} )} & ( Expression 2 ) \\ I 9 = I 2 = Io \cdot \frac{W 2}{L 2} \cdot {ɛ}^{( \frac{Vg 2 / n - Vs}{Vt} )} & ( Expression 3 )\end{matrix}$$

where
Vg1=Vref
Vg2=Vin
Vs=a source voltage common to the transistors T1 and T2 (a voltage between the transistors T1 and T2 and the current source 10).
W1 and L1 are the gate width and the gate length of the transistor T1, respectively.
W2 and L2 are the gate width and the gate length of the transistor T2, respectively.
Io is a constant depending on a process.

As described above, when the logic level of the output part OUT is inverted, the currents I4 and I9 are almost equal to each other. That is, the expression 1 is obtained by solving I4=I9.

In the expression 1, n is a value determined by a manufacturing process of the comparator 1. Vt is a physical constant (a thermal voltage) determined by a temperature. That is, the hysteresis voltage Vhys can be changed by changing α (that is, the ratio between (the size of the transistor T3+the size of the transistor T5) and the size of the transistor T4). In other words, the hysteresis voltage Vhys can be set based on the ratio between W3/L3+W5/L5 and W4/L4 (the mirror ratio (a third mirror ratio) of the third mirror circuit MRR3).

If the first transistor T1 and the second transistor T2 operate in a strong inversion region (a linear region or a saturated region), other characteristics such as a threshold voltage of the first transistor T1 and the second transistor T2 need to be considered. Therefore, a design of the comparator 1 to obtain desired hysteresis characteristics becomes difficult.

On the other hand, because the first transistor T1 and the second transistor T2 operate in a weak inversion region in the first embodiment, the above expression 1 holds and desired hysteresis characteristics can be easily obtained by changing the mirror ratio of the third mirror circuit MRR3. Accordingly, the comparator 1 according to the first embodiment can be designed relatively easily to provide the desired hysteresis characteristics.

The comparator 1 according to the first embodiment uses the MISFETs as the fifth transistor T5 and the switching element SW without using a resistive element for the hysteresis characteristics. Therefore, a large resistive element is not required to reduce the current consumption.

Accordingly, the comparator 1 can have a relatively small layout area while the current consumption is reduced. The comparator 1 achieves reduction in the current consumption because the first transistor T1 and the second transistor T2 operate in a weak inversion region. Furthermore, because the comparator 1 does not use a resistive element for the hysteresis circuit HYS, a CR time constant can be set at a smaller value. This enables the comparator 1 to operate at a relatively high speed. In the first embodiment, the reference voltage Vref itself is used as a setting value without generating a setting value by dividing the reference voltage Vref with a resistor. Therefore, the range of the operation voltage of the comparator 1 (the range of the reference voltage Vref or the range of the output voltage, for example) can be widened as compared to the conventional techniques.

### Second Embodiment

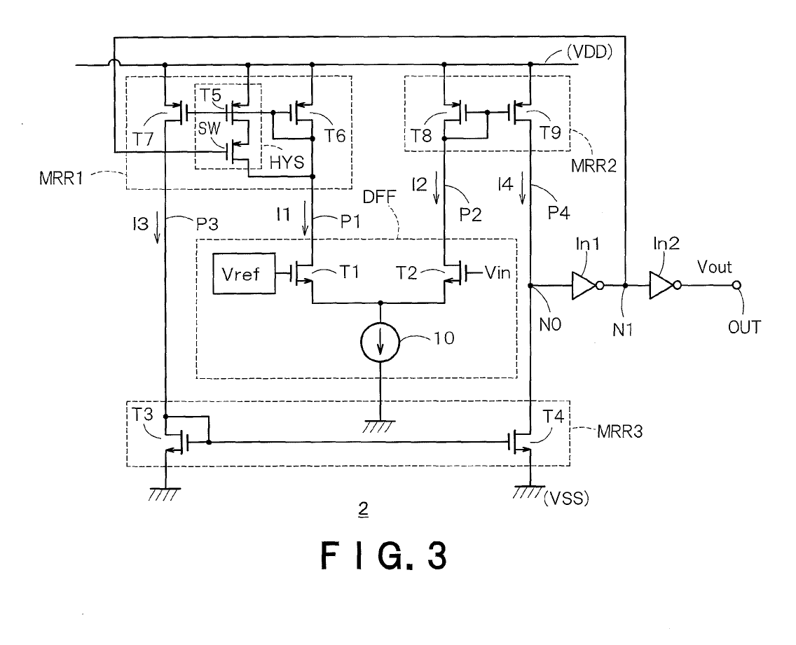

FIG. 3 is a circuit diagram showing an example of a configuration of a comparator 2 according to a second embodiment. In the second embodiment, the hysteresis circuit HYS is not provided in the third mirror circuit MRR3 but in the first mirror circuit MRR1. The fifth transistor T5 of the hysteresis circuit HYS is, for example, a P-MISFET. One end of the fifth transistor T5 is connected to the first current path P1 via the switching element SW and the other end thereof is connected to the first power supply VDD. The gate of the fifth transistor T5 is connected together with the gates of the sixth and seventh transistors T6 and T7 to the first current path P1 in common. Accordingly, when the switching element SW is in a conduction state, the fifth transistor T5 is connected in parallel to the sixth transistor T6. In this case, the size (W5/L5) of the fifth transistor T5 is added to the size (W6/L6) of the sixth transistor T6. That is, it can be considered that the size of the sixth transistor T6 is substantially increased. On the other hand, when the switching element SW is in a non-conduction state, the one end of the fifth transistor T5 is disconnected from the sixth transistor T6 and the first current path P1. In this case, the size of the fifth transistor T5 is not added to the size of the sixth transistor T6. Therefore, the size of the sixth transistor T6 remains relatively small. It is assumed that the channel widths of the sixth and seventh transistors T6 and T7 are W6 and W7 and the channel lengths thereof are L6 and L7, respectively.

The switching element SW is, for example, a P-MISFET and is connected between the first current path P1 and the fifth transistor T5. The gate of the switching element SW is connected to a node N1 between the inverter In1 and the inverter In2. That is, the gate of the switching element SW receives the inverse logic level of a logic level of the output part OUT. Accordingly, the switching element SW is brought to the conduction state or the non-conduction state according to the inverse logic level of a logic level of the output part OUT. However, because the switching element SW is a P-MISFET, the switching element SW is brought to the conduction state when the output part OUT is at logic high (the node N1 is at logic low) and is brought to the non-conduction state when the output part OUT is at logic low (the node N1 is at logic high) similarly to the switching element SW in the first embodiment.

Alternatively, the switching element SW can be connected between the fifth transistor T5 and the first power supply VDD. That is, it suffices to connect the switching element SW in series with the fifth transistor T5.

The fifth transistor T5 is connected in parallel to the sixth transistor T6 or electrically disconnected from the sixth transistor T6 by the switching element SW that is brought to the conduction state or the non-conduction state in the above manner. Accordingly, the size of the fifth transistor T5 is added or not added to the size of the sixth transistor T6 according to a logic level of the output part OUT. That is, the hysteresis circuit HYS can substantially change the size of the sixth transistor T6 according to a logic level of the output part OUT. This enables the comparator 2 to provide hysteresis characteristics in the relation between the input voltage Vin and the output voltage Vout. Other configurations of the second embodiment can be identical to corresponding ones of the first embodiment.

An operation of the comparator 2 according to the second embodiment is explained next.

First, when the input voltage Vin is lower than the reference voltage Vref, the first transistor T1 is brought to the conduction state and the second transistor T2 is brought to the non-conduction state. Accordingly, the current I1 flows through the first current path P1 and the first mirror circuit MRR1 causes the current I3 corresponding to the current I1 to flow through the third current path P3 because the first transistor T1 is brought to the conduction state. At that time, the node N1 is at logic high as will be described later and thus the switching element SW is in the non-conduction state. Therefore, the mirror ratio (I3/I1) of the first mirror circuit MRR1 is a ratio ((W7/L7)/(W6/L6)) between the size (W7/L7) of the seventh transistor T7 and the size (W6/L6) of the sixth transistor T6. The third mirror circuit MRR3 attempts to cause the current I4 corresponding to the current I3 to flow through the fourth current path P4.

Meanwhile, no current flows through the second current path P2 and the second mirror circuit MRR2 does not cause a current to flow from the first power supply VDD to the fourth current path P4. Therefore, the output part OUT outputs logic low.

That is, the logic level of the node N1 becomes logic high and thus the switching element SW is in the non-conduction state. Because the switching element SW is in the non-conduction state, the fifth transistor T5 is electrically disconnected from the first current path P1 and the sixth transistor T6 and thus does not cause a current to flow through. Therefore, at that time, the size of the fifth transistor T5 is not added to the size of the sixth transistor T6.

### (Case 3: When Input Voltage Vin Exceeds Reference Voltage Vref)

Next, when the input voltage Vin increases and the input voltage Vin exceeds the reference voltage Vref, the second transistor T2 is brought to the conduction state and the first transistor T1 is brought to the non-conduction state. Accordingly, the current I2 flows through the second current path P2 and the second mirror circuit MRR2 attempts to cause the current I4 corresponding to the current I2 to flow through the fourth current path P4. Meanwhile, no current flows through the first current path P1 and the first mirror circuit MRR1 does not cause a current to flow from the first power supply VDD to the third current path P3. Therefore, the gates of the third and fourth transistors T3 and T4 become at a low-level voltage and the third and fourth transistors T3 and T4 are brought to the non-conduction state. The node N0 of the fourth current path P4 thereby becomes at a high-level voltage and the voltage Vout also becomes a high-level voltage. That is, the output part OUT outputs logic high.

Because the node N1 becomes at logic low, the switching element SW is brought to the conduction state. Therefore, the fifth transistor T5 is connected in parallel to the sixth transistor T6 and enables a current to flow together with the sixth transistor T6. At that time, accordingly, the size of the fifth transistor T5 is added to the size of the sixth transistor T6. That is, it can be considered that a substantial size of the sixth transistor T6 is increased by the size of the fifth transistor T5.

### (Case 4: When Input Voltage Vin Falls Below Reference Voltage Vref)

A case where the input voltage Vin lowers to fall below the reference voltage Vref is considered next. When the logic level of the output part OUT is high, the switching element SW is brought to the conduction state and thus the fifth transistor T5 is connected in parallel to the sixth transistor T6. In this case, the size of the fifth transistor T5 is added to the size of the sixth transistor T6. Therefore, the mirror ratio (I3/I1) of the first mirror circuit MRR1 is a ratio ((W7/L7)/(W6/L6)+(W5/L5)) between the total size of the sixth and fifth transistors T6 and T5 and the size of the seventh transistor T7. Accordingly, the mirror ratio of the first mirror circuit MRR1 at a time when the switching element SW is in the conduction state (the case 4) is smaller than that of the first mirror circuit MRR1 at a time when the switching element SW is in the non-conduction state (the case 3). That is, a current flowing in the seventh transistor T7 in the case 4 is smaller than that flowing in the seventh transistor T7 in the case 3. The current I3 flowing through the third current path P3 is reduced. With reduction in the current I3, a current caused by the third mirror circuit MRR3 to flow in the fourth transistor T4 is also reduced. Accordingly, a current flowing in the fourth transistor T4 is also reduced as compared to a time when the switching element SW is in the conduction state.

The conduction state of the fourth transistor T4 and the conduction state of the ninth transistor T9 are switched at a time when the logic level of the output part OUT is inverted as described above. At the switching, a current value flowing in the fourth transistor T4 and a current value flowing in the ninth transistor T9 are almost equal to each other. Therefore, when a current flowing in the fourth transistor T4 is reduced by the fifth transistor T5 connected in parallel to the sixth transistor T6, a current flowing in the ninth transistor T9 when the logic level of the output part OUT is inverted is also reduced. As a result, also the comparator 2 has hysteresis characteristics.

Also in the second embodiment, the current source 10 causes a weak constant current (a tail current) to flow in the first transistor T1 and/or the second transistor T2 to operate the first transistor T1 and the second transistor T2 in a weak inversion region. Accordingly, the hysteresis voltage Vhys of the comparator 2 is also represented by the expression 1. However, α is (the size of the transistor T6+the size of the transistor T5)/the size of the transistor T7 and is, that is, ((W6/L6)+(W5/L5))/(W7/L7). That is, the hysteresis voltage Vhys of the comparator 2 is represented by an expression 4.

Vhys=n×Vt×In((W5/L5+W6/L6)/(W7/L7)) Expression 4

In this way, also the comparator 2 can change the hysteresis voltage Vhys by changing α (that is, the ratio between (the size of the transistor T6+the size of the transistor T5) and the size of the transistor T7). In other words, the hysteresis voltage Vhys is determined based on the ratio between (W5/L5+W6/L6) and W7/L7 and can be adjusted by changing the mirror ratio (a first mirror ratio) of the first mirror circuit MRR1. As described above, because the first transistor T1 and the second transistor T2 operate in a weak inversion region also in the second embodiment similarly to the first embodiment, the above expression 4 holds and desired characteristics can be easily obtained by changing the mirror ratio of the first mirror circuit MRR1. Furthermore, the second embodiment can achieve effects identical to those of the first embodiment.

### Third Embodiment

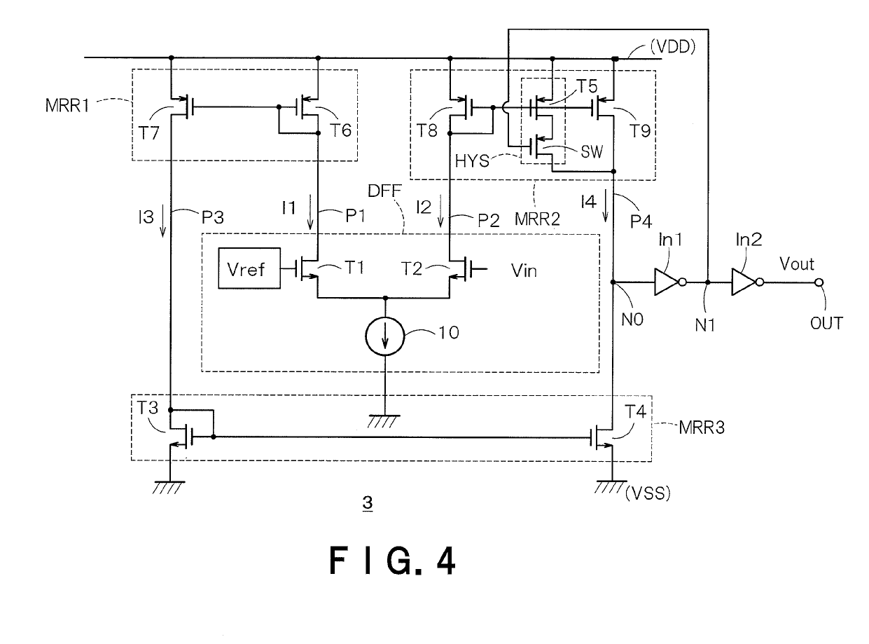

FIG. 4 is a circuit diagram showing an example of a configuration of a comparator 3 according to a third embodiment. In the third embodiment, the hysteresis circuit HYS is provided for the ninth transistor T9 in the second mirror circuit MRR2. The fifth transistor T5 of the hysteresis circuit HYS is, for example, a P-MISFET. One end of the fifth transistor T5 is connected to the fourth current path P4 via the switching element SW and the other end thereof is connected to the first power supply VDD. The gate of the fifth transistor T5 is connected together with the gates of the eighth and ninth transistors T8 and T9 to the second current path P2 in common. Accordingly, when the switching element SW is in a conduction state, the fifth transistor T5 is connected in parallel to the ninth transistor T9. In this case, the size (W5/L5) of the fifth transistor T5 is added to the size (W9/L9) of the ninth transistor T9. That is, it can be considered that the size of the ninth transistor T9 is substantially increased. On the other hand, when the switching element SW is in a non-conduction state, the one end of the fifth transistor T5 is disconnected from the ninth transistor T9 and the fourth current path P4. In this case, the size of the fifth transistor T5 is not added to the size of the ninth transistor T9.

The switching element SW is a P-MISFET and is connected between the fourth current path P4 and the fifth transistor T5. The gate of the switching element SW is connected to the node N1. That is, the gate of the switching element SW receives the inverse logic level of data from the output part OUT. Accordingly, the switching element SW is brought to the conduction state or the non-conduction state according to the inverse logic level of data from the output part OUT. Alternatively, the switching element SW can be connected between the fifth transistor T5 and the first power supply VDD. That is, it suffices to connect the switching element SW in series with the fifth transistor T5.

The fifth transistor T5 is connected in parallel to the ninth transistor T9 or electrically disconnected from the ninth transistor T9 by the switching element SW that is brought to the conduction state or the non-conduction state in the above manner. The size of the fifth transistor T5 is thereby added or not added to the size of the ninth transistor T9 according to a logic level of the output part OUT. That is, the hysteresis circuit HYS can substantially change the size of the ninth transistor T9 according to a logic level of the output part OUT. Accordingly, the comparator 3 can provide hysteresis characteristics in the relation between the input voltage Vin and the output voltage Vout. Other configurations of the third embodiment can be identical to corresponding ones of the first embodiment.

When the input voltage Vin is lower than the reference voltage Vref and the output part OUT is at logic low (the node N1 is at logic high), the switching element SW is in the non-conduction state. Therefore, the mirror ratio (I4/I2) of the second mirror circuit MRR2 is a ratio ((W9/L9)/(W8/L8)) between the size of the ninth transistor T9 and the size of the eighth transistor T8.

On the other hand, when the output part OUT becomes at logic high in the above case 1 (when the input voltage Vin exceeds the reference voltage Vref), the switching element SW is brought to the conduction state and thus the fifth transistor T5 is connected in parallel to the ninth transistor T9. At that time, therefore, the size of the fifth transistor T5 is added to the size of the ninth transistor T9.

When the logic level of the output part OUT is high in the above case 2 (when the input voltage Vin falls below the reference voltage Vref), the fifth transistor T5 is connected in parallel to the ninth transistor T9. Therefore, the mirror ratio (I4/I2) of the second mirror circuit MRR2 is a ratio ((W5/L5)+(W9/L9)/(W8/L8)) between the total size of the fifth and ninth transistors T5 and T9 and the size of the eighth transistor T8. Therefore, the mirror ratio of the second mirror circuit MRR2 in the case 2 is larger than that in the case 1. Accordingly, a current that can flow in the ninth transistor T9 in the case 2 is larger than that can flow in the ninth transistor T9 in the case 1.

As described above, it is considered that the logic level of the output part OUT is inverted when the current value flowing in the fourth transistor T4 and the current value flowing in the ninth transistor T9 are almost equal to each other. Therefore, when the logic level of the output part OUT in the case 2 is inverted, the current flowing in the ninth transistor T9 is reduced to an identical level to the current flowing in the fourth transistor T4. That is, the current flowing in the ninth transistor T9 when the logic level of the output part OUT is inverted is smaller in the case 2 than in the case 1. Because the current flowing in the ninth transistor T9 depends on the current flowing in the eighth transistor T8, the current I2 flowing in the eighth transistor T8 when the logic level of the output part OUT is inverted is also smaller in the case 2 than in the case 1. That is, in the case 2, the logic level of the output part OUT is inverted when the current I2 becomes smaller. This means that the logic level of the output part OUT is inverted when the input voltage Vin falls below a voltage (the second reference voltage Vref-Vhys) lower than the reference voltage Vref. As a result, the comparator 3 according to the third embodiment has hysteresis characteristics.

The hysteresis voltage Vhys of the comparator 3 is represented by an expression 5.

Vhys=n×V×In((W5/L5+W9/L9)/(W8/L8)) Expression 5

In this way, also the comparator 3 can change the hysteresis voltage Vhys by changing α (that is, the ratio between (the size of the transistor T5+the size of the transistor T9) and the size of the transistor T8). In other words, the hysteresis voltage Vhys is determined based on the ratio between (W5/L5+W9/L9) and W8/L8 and can be adjusted by changing the mirror ratio (a second mirror ratio) of the second mirror circuit MRR2. Because the first transistor T1 and the second transistor T2 operate in a weak inversion region also in the third embodiment similarly to the first embodiment, the above expression 5 holds and desired hysteresis characteristics can be easily obtained by changing the mirror ratio of the second mirror circuit MRR2. Furthermore, the third embodiment can achieve effects identical to those of the first embodiment.

### Fourth Embodiment

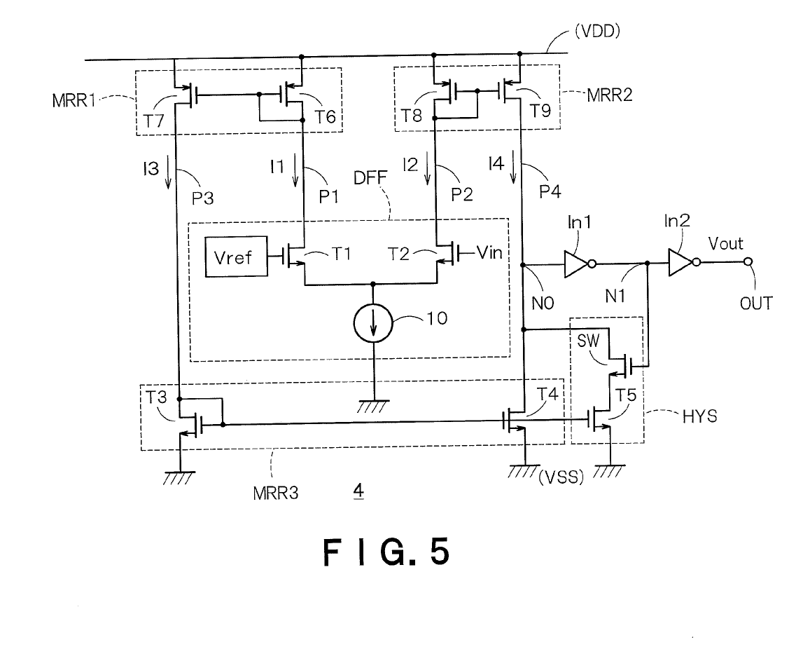

FIG. 5 is a circuit diagram showing an example of a configuration of a comparator 4 according to a fourth embodiment. In the fourth embodiment, the hysteresis circuit HYS is provided for the fourth transistor T4 in the third mirror circuit MRR3. The fifth transistor T5 of the hysteresis circuit HYS is, for example, an N-MISFET. One end of the fifth transistor T5 is connected the fourth current path P4 via the switching element SW and the other end thereof is connected to the second power supply VSS. The gate of the fifth transistor T5 is connected together with the gates of the third and fourth transistors T3 and T4 to the third current path P3 in common. Accordingly, when the switching element SW is in a conduction state, the fifth transistor T5 is connected in parallel to the fourth transistor T4. In this case, the size (W5/L5) of the fifth transistor T5 is added to the size (W4/L4) of the fourth transistor T4. That is, it can be considered that the size of the fourth transistor T4 is substantially increased. On the other hand, when the switching element SW is in a non-conduction state, the one end of the fifth transistor T5 is disconnected from the fourth transistor T4 and the fourth current path P4. In this case, the size of the fifth transistor T5 is not added to the size of the fourth transistor T4.

The switching element SW is an N-MISFET and is connected between the fourth current path P4 and the fifth transistor T5. The gate of the switching element SW is connected to the node N1 between the inverter In1 and the inverter In2. That is, the gate of the switching element SW receives the inverse logic level of data from the output part OUT. Accordingly, the switching element SW is brought to the conduction state or the non-conduction state according to the inverse logic level of data from the output part OUT. Because the switching element SW receives the inverse logic level of data from the output part OUT, the switching element SW is brought to the non-conduction state when the output part OUT is at logic high (the node N1 is at logic low) and is brought to the conduction state when the output part OUT is at logic low (the node N1 is at logic high) conversely to the switching element SW according to the first embodiment. Alternatively, the switching element SW can be connected between the fifth transistor T5 and the second power supply VSS. That is, it suffices to connect the switching element SW in series with the fifth transistor T5.

The fifth transistor T5 is connected in parallel to the fourth transistor T4 or is electrically disconnected from the fourth transistor T4 by the switching element SW that is brought to the conduction state or the non-conduction state in the above manner. The size of the fifth transistor T5 is thereby added or not added to the size of the fourth transistor T4 according to a logic level of the output part OUT. That is, the hysteresis circuit HYS can substantially change the size of the fourth transistor T4 according to a logic level of the output part OUT. This enables the comparator 4 to provide hysteresis characteristics in the relation between the input voltage Vin and the output voltage Vout. Other configurations of the fourth embodiment can be identical to corresponding ones of the first embodiment.

When the input voltage Vin is lower than the reference voltage Vref and the output part OUT is at logic low (the node N1 is at logic high), the switching element SW is in the conduction state.

Therefore, the mirror ratio (I4/I3) of the third mirror circuit MRR3 is a ratio ((W4/L4)+(W5/L5)/(W3/L3)) between the total size of the fourth and fifth transistors T4 and T5 and the size of the third transistor T3. That is, the size of the fifth transistor T5 is added to the size of the fourth transistor T4. It can be considered that a substantial size of the fourth transistor T4 is increased by the size of the fifth transistor T5.

On the other hand, when the output part OUT becomes at logic high in the above case 1 (when the input voltage Vin exceeds the reference voltage Vref), the switching element SW is brought to the non-conduction state and thus the fifth transistor T5 is electrically disconnected from the fourth current path P4 and the fourth transistor T4. At that time, therefore, the size of the fifth transistor T5 is not added to the size of the fourth transistor T4. In this way, in the fourth embodiment, the hysteresis characteristics are obtained by changing the size of the fourth transistor T4.

In the first embodiment, when the output part OUT is at logic high, the fifth transistor T5 is connected in parallel to the third transistor T3, thereby lowering the reference voltage Vref by the hysteresis voltage Vhys.

On the other hand, in the fourth embodiment, when the output part OUT is at logic low, the fifth transistor T5 is connected in parallel to the fourth transistor T4, thereby increasing the reference voltage Vref by the hysteresis voltage Vhys. Therefore, when the output part OUT becomes at logic high and the fifth transistor T5 is electrically disconnected from the fourth transistor T4, the reference voltage is changed from Vref+Vhys to Vref and is lowered substantially by the hysteresis voltage Vhys. Accordingly, the comparator 4 according to the fourth embodiment can have hysteresis characteristics substantially identical to those of the first embodiment.

The hysteresis voltage Vhys of the comparator 4 is represented by an expression 11.

Vhys=n×Vt×In((W4/L4+W5/L5)/(W3/L3)) Expression 11

In this way, also the comparator 4 can change the hysteresis voltage Vhys by changing α (that is, the ratio between (the size of the transistor T4+the size of the transistor T5) and the size of the transistor T3). In other words, the hysteresis voltage Vhys is determined based on the ratio between (W4/L4+W5/L5) and W3/L3 and can be adjusted by changing the mirror ratio (the third mirror ratio) of the third mirror circuit MRR3. Because the first transistor T1 and the second transistor T2 operate in a weak inversion region also in the fourth embodiment similarly to the first embodiment, the above expression 11 holds and desired hysteresis characteristics can be easily obtained by changing the mirror ratio of the third mirror circuit MRR3. Furthermore, the fourth embodiment can achieve effects identical to those of the first embodiment.

### Fifth Embodiment

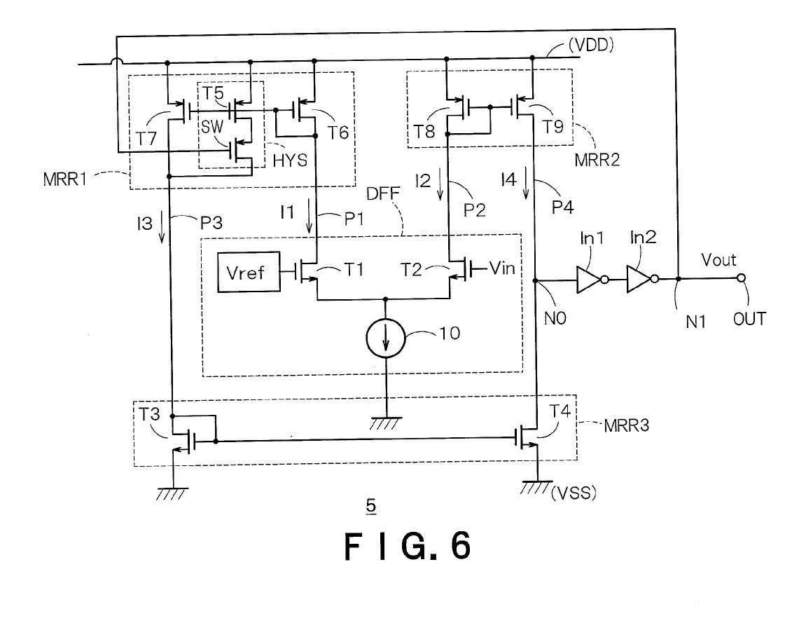

FIG. 6 is a circuit diagram showing an example of a configuration of a comparator 5 according to a fifth embodiment. In the fifth embodiment, the hysteresis circuit HYS is provided for the seventh transistor T7 in the first mirror circuit MRR1. The fifth transistor T5 in the hysteresis circuit HYS is, for example, a P-MISFET. One end of the fifth transistor T5 is connected to the third current path P3 via the switching element SW and the other end thereof is connected to the first power supply VDD. The gate of the fifth transistor T5 is connected together with the gates of the sixth and seventh transistors T6 and T7 to the first current path P1 in common. Accordingly, when the switching element SW is in a conduction state, the fifth transistor T5 is connected in parallel to the seventh transistor T7. In this case, the size (W5/L5) of the fifth transistor T5 is added to the size (W7/L7) of the seventh transistor T7. That is, it can be considered that the size of the seventh transistor T7 is substantially increased. On the other hand, when the switching element SW is in a non-conduction state, the one end of the fifth transistor T5 is disconnected from the seventh transistor T7 and the third current path P3. In this case, the size of the fifth transistor T5 is not added to the size of the seventh transistor T7.

The switching element SW is a P-MISFET and is connected between the third current path P3 and the fifth transistor T5. The gate of the switching element SW is connected to the output part OUT. That is, the gate of the switching element SW receives a logic level of the output part OUT.

Accordingly, the switching element SW is brought to the conduction state or the non-conduction state according to a logic level of the output part OUT. Because the switching element SW receives a logic level of the output part OUT, the switching element SW is brought to the non-conduction state when the output part OUT is at logic high (the node N1 is at logic high) and is brought to the conduction state when the output part OUT is at logic low (the node N1 is at logic low) conversely to the switching element SW according to the second embodiment. Alternatively, the switching element SW can be connected between the fifth transistor T5 and the first power supply VDD. That is, it suffices to connect the switching element SW in series with the fifth transistor T5.

The fifth transistor T5 is connected in parallel to the seventh transistor T7 or is electrically disconnected from the seventh transistor T7 by the switching element SW that is brought to the conduction state or the non-conduction state in the above manner. The size of the fifth transistor T5 is thereby added or not added to the size of the seventh transistor T7 according to a logic level of the output part OUT. That is, the hysteresis circuit HYS can substantially change the size of the seventh transistor T7 according to a logic level of the output part OUT. Accordingly, the comparator 5 can provide hysteresis characteristics in the relation between the input voltage Vin and the output voltage Vout. Other configurations of the fifth embodiment can be identical to corresponding ones of the second embodiment.

In this example, when the input voltage Vin is lower than the reference voltage Vref and the output part OUT is at logic low, the switching element SW is in the conduction state. Therefore, the mirror ratio (I3/I1) of the first mirror circuit MRR1 is a ratio ((W5/L5)+(W7/L7)/(W6/L6)) between the total size of the fifth and seventh transistors T5 and T7 and the size of the sixth transistor T6. That is, the size of the fifth transistor T5 is added to the size of the seventh transistor T7. It can be considered that a substantial size of the seventh transistor T7 is increased by the size of the fifth transistor T5.

On the other hand, when the output part OUT becomes at logic high in the above case 3 (when the input voltage Vin exceeds the reference voltage Vref), the switching element SW is brought to the non-conduction state and thus the fifth transistor T5 is electrically disconnected from the third current path P3 and the seventh transistor T7. At that time, therefore, the size of the fifth transistor T5 is not added to the size of the seventh transistor T7. In this way, in the fifth embodiment, the hysteresis characteristics are obtained by changing the size of the seventh transistor T7.

In the second embodiment, the reference voltage Vref is lowered by the hysteresis voltage Vhys due to the fifth transistor T5 connected in parallel to the sixth transistor T6 when the output part OUT is at logic high (the node N1 is at logic low).

On the other hand, in the fifth embodiment, the reference voltage Vref is increased by the hysteresis voltage Vhys due to the fifth transistor T5 connected in parallel to the seventh transistor T7 when the output part OUT is at logic low (the node N1 is at logic high). Therefore, when the output part OUT becomes at logic high and the fifth transistor T5 is electrically disconnected from the seventh transistor T7, the reference voltage is changed from Vref+Vhys to Vref and is lowered substantially by the hysteresis voltage Vhys. Accordingly, the comparator 5 according to the fifth embodiment can have hysteresis characteristics substantially identical to those of the second embodiment.

The hysteresis voltage Vhys of the comparator 5 is represented by an expression 12.

Vhys=n×Vt×In((W5/L5+W7/L7)/(W6/L6)) Expression 12

In this way, also the comparator 5 can change the hysteresis voltage Vhys by changing α (that is, the ratio between (the size of the transistor T7+the size of the transistor T5) and the size of the transistor T6). In other words, the hysteresis voltage Vhys is determined based on the ratio between (W5/L5+W7/L7) and W6/L6 and can be adjusted by changing the mirror ratio (the first mirror ratio) of the first mirror circuit MRR1. Because the first transistor T1 and the second transistor T2 operate in a weak inversion region also in the fifth embodiment similarly to the second embodiment, the above expression 12 holds and desired hysteresis characteristics can be easily obtained by changing the mirror ratio of the first mirror circuit MRR1. Furthermore, the fifth embodiment can achieve effects identical to those of the second embodiment.

### Sixth Embodiment

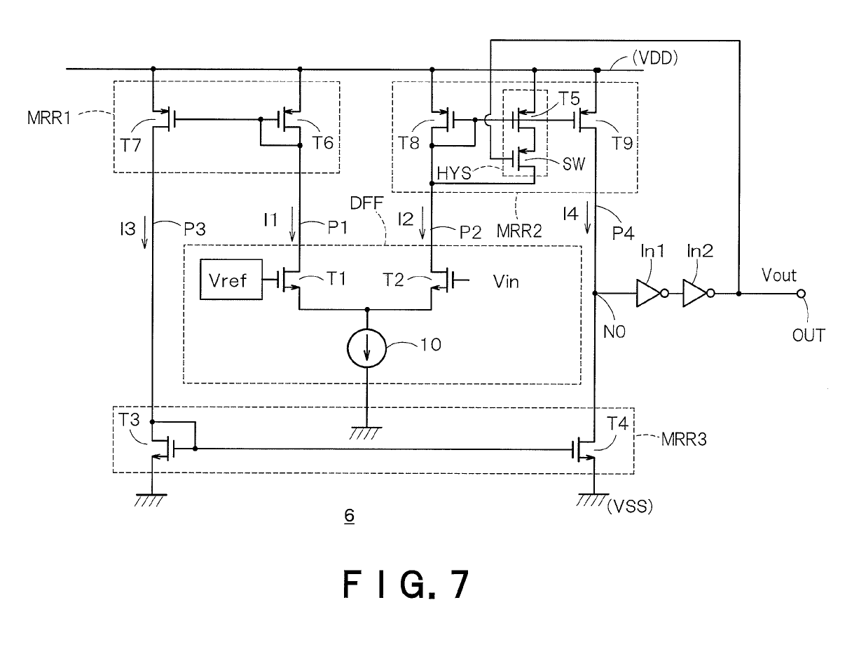

FIG. 7 is a circuit diagram showing an example of a configuration of a comparator 6 according to a sixth embodiment. In the sixth embodiment, the hysteresis circuit HYS is provided for the eighth transistor T8 in the second mirror circuit MRR2. The fifth transistor T5 of the hysteresis circuit HYS is, for example, a P-MISFET. One end of the fifth transistor T5 is connected to the second current path P2 via the switching element SW and the other end thereof is connected to the first power supply VDD. The gate of the fifth transistor T5 is connected together with the gates of the eighth and ninth transistors T8 and T9 to the second current path P2 in common. Accordingly, when the switching element SW is in a conduction state, the fifth transistor T5 is connected in parallel to the eighth transistor T8. In this case, the size (W5/L5) of the fifth transistor T5 is added to the size (W8/L8) of the eighth transistor T8. That is, it can be considered that the size of the eighth transistor T8 is substantially increased. On the other hand, when the switching element SW is in a non-conduction state, the one end of the fifth transistor T5 is disconnected from the eighth transistor T8 and the second current path P2. In this case, the size of the fifth transistor T5 is not added to the size of the eighth transistor T8.

The switching element SW is a P-MISFET and is connected between the second current path P2 and the fifth transistor T5. The gate of the switching element SW is connected to the output part OUT. That is, the gate of the switching element SW receives a logic level of the output part OUT.

Accordingly, the switching element SW is brought to the conduction state or the non-conduction state according to a logic level of the output part OUT. Because the switching element SW receives a logic level of the output part OUT, the switching element SW is brought to the non-conduction state when the output part OUT is at logic high and is brought to the conduction state when the output part OUT is at logic low conversely to the switching element SW according to the third embodiment. Alternatively, the switching element SW can be connected between the fifth transistor T5 and the first power supply VDD. That is, it suffices to connect the switching element SW in series with the fifth transistor T5.

The fifth transistor T5 is connected in parallel to the eighth transistor T8 or is electrically disconnected from the eighth transistor T8 by the switching element SW that is brought to the conduction state or the non-conduction state in the above manner. The size of the fifth transistor T5 is thereby added or not added to the size of the eighth transistor T8 according to a logic level of the output part OUT. That is, the hysteresis circuit HYS can substantially change the size of the eighth transistor T8 according to a logic level of the output part OUT. Accordingly, the comparator 6 can provide hysteresis characteristics in the relation between the input voltage Vin and the output voltage Vout. Other configurations of the sixth embodiment can be identical to corresponding ones of the third embodiment.

In this example, when the input voltage Vin is lower than the reference voltage Vref and the output part OUT is at logic low, the switching element SW is in the conduction state. Therefore, the mirror ratio (I4/I2) of the second mirror circuit MRR2 is a ratio (W9/L9)/((W5/L5)+(W8/L8)) between the total size of the fifth and eighth transistors T5 and T8 and the size of the ninth transistor T9. That is, the size of the fifth transistor T5 is added to the size of the eighth transistor T8. It can be considered that a substantial size of the eighth transistor T8 is increased by the size of the fifth transistor T5.

On the other hand, when the output part OUT becomes at logic high in the above case 1 (when the input voltage Vin exceeds the reference voltage Vref), the switching element SW is brought to the non-conduction state and thus the fifth transistor T5 is electrically disconnected from the second current path P2 and the eighth transistor T8. At that time, therefore, the size of the fifth transistor T5 is not added to the size of the eighth transistor T8. In this way, in the sixth embodiment, the hysteresis characteristics are obtained by changing the size of the eighth transistor T8.

In the third embodiment, the reference voltage Vref is lowered by the hysteresis voltage Vhys due to the fifth transistor T5 connected in parallel to the ninth transistor T9 when the output part OUT is at logic high.

On the other hand, in the sixth embodiment, the reference voltage Vref is increased by the hysteresis voltage Vhys due to the fifth transistor T5 connected in parallel to the eighth transistor T8 when the output part OUT is at logic low. Therefore, when the output part OUT becomes at logic high and the fifth transistor T5 is electrically disconnected from the eighth transistor T8, the reference voltage is changed from Vref+Vhys to Vref and is lowered substantially by the hysteresis voltage Vhys. Accordingly, the comparator 6 according to the sixth embodiment can have hysteresis characteristics substantially identical to those of the third embodiment.

The hysteresis voltage Vhys of the comparator 6 is represented by an expression 13.

Vhys=n×Vt×In((W5/L5+W8/L8)/(W9/L9)) Expression 13

In this way, also the comparator 6 can change the hysteresis voltage Vhys by changing 60 (that is, the ratio between (the size of the transistor T5+the size of the transistor T8) and the size of the transistor T9). In other words, the hysteresis voltage Vhys is determined based on the ratio between (W5/L5+W8/L8) and W9/L9 and can be adjusted by changing the mirror ratio (the second mirror ratio) of the second mirror circuit MRR2. Because the first transistor T1 and the second transistor T2 operate in a weak inversion region also in the sixth embodiment similarly to the third embodiment, the above expression 13 holds and desired hysteresis characteristics can be easily obtained by changing the mirror ratio of the second mirror circuit MRR2. Furthermore, the sixth embodiment can achieve effects identical to those of the third embodiment.

In the above embodiments, the conduction type of the switching element SW can be changed between the N type and the P type. In this case, it suffices to invert the logic level of data to be received by the gate of the switching element SW by changing a connection point of the gate of the switching element SW between the output part OUT and the node N1.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device comprising:
a differential circuit comprising a first current path receiving a first voltage and a second current path receiving a second voltage;
a first mirror circuit capable of causing a current obtained by multiplying a current flowing through the first current path by a first mirror ratio to flow through a third current path;
a second mirror circuit capable of causing a current obtained by multiplying a current flowing through the second current path by a second mirror ratio to flow through a fourth current path;
a third mirror circuit capable of causing a current obtained by multiplying a current flowing through the third current path by a third mirror ratio to flow through the fourth current path; and
a first circuit changing any one of the first to third mirror ratios according to a logic level of data output from an output part connected to the fourth current path.

2. The device of claim 1, wherein a voltage difference between the second voltage at a time when the output part is switched from a first logic level to a second logic level and the second voltage at a time when the output part is switched from the second logic level to the first logic level is determined based on the changed one of the first to third mirror ratios.

3. The device of claim 1, wherein
the differential circuit comprises a first transistor provided on the first current path and receiving the first voltage at a gate thereof, and a second transistor provided on the second current path and receiving the second voltage at a gate thereof,
the third mirror circuit comprises a third transistor provided on the third current path, and a fourth transistor provided on the fourth current path, gates of the third and fourth transistors being connected to the third current path in common, and
the first circuit comprises a fifth transistor having a gate connected to the third current path, the fifth transistor being connected in parallel to the third or fourth transistor or disconnected from the third or fourth transistor according to a logic level of the output part.

4. The device of claim 3, wherein assuming that a channel width and a channel length of the third transistor are W3 and L3, respectively, a channel width and a channel length of the fourth transistor are W4 and L4, respectively, and a channel width and a channel length of the fifth transistor are W5 and L5, respectively, a voltage difference between the second voltage at a time when the output part is switched from a first logic level to a second logic level and the second voltage at a time when the output part is switched from the second logic level to the first logic level is determined based on a ratio between W3/L3+W5/L5 and W4/L4 or a ratio between W4/L4+W5/L5 and W3/L3.

5. The device of claim 3, wherein the first and second transistors operate in a weak inversion region.

6. The device of claim 3, wherein the first circuit further comprises a switching element connected in series with the fifth transistor and having a gate connected to the output part.

7. The device of claim 6, wherein the switching element is brought to a non-conduction state when a voltage of the output part has a first logic level and is brought to a conduction state when a voltage of the output part has a second logic level.

8. The device of claim 3, wherein
assuming that a channel width and a channel length of the third transistor are W3 and L3, respectively, a channel width and a channel length of the fourth transistor are W4 and L4, respectively, and a channel width and a channel length of the fifth transistor are W5 and L5, respectively, the voltage difference Vhys is determined by an expression 1 or an expression 11
Vhys=n×Vt×In((W3/L3+W5/L5)/(W4/L4)) Expression 1
Vhys=n×Vt×In((W4/L4+W5/L5)/(W3/L3)) Expression 11
(where n is a constant determined by a semiconductor manufacturing process and Vt is a thermal voltage).

9. The device of claim 1, wherein
the differential circuit comprises a first transistor provided on the first current path and receiving the first voltage at a gate thereof, and a second transistor provided on the second current path and receiving the second voltage at a gate thereof,
the first mirror circuit comprises a sixth transistor provided on the first current path, and a seventh transistor provided on the third current path, gates of the sixth and seventh transistors being connected to the first current path in common, and
the first circuit comprises a fifth transistor having a gate connected to the first current path, the fifth transistor being connected in parallel to the sixth or seventh transistor or disconnected from the sixth or seventh transistor according to a logic level of the output part.

10. The device of claim 9, wherein assuming that a channel width and a channel length of the fifth transistor are W5 and L5, respectively, a channel width and a channel length of the sixth transistor are W6 and L6, respectively, and a channel width and a channel length of the seventh transistor are W7 and L7, respectively, a voltage difference between the second voltage at a time when the output part is switched from a first logic level to a second logic level and the second voltage at a time when the output part is switched from the second logic level to the first logic level is determined based on a ratio between W5/L5+W6/L6 and W7/L7 or a ratio between W5/L5+W7/L7 and W6/L6.

11. The device of claim 9, wherein the first and second transistors operate in a weak inversion region.

12. The device of claim 9, wherein the first circuit further comprises a switching element connected in series with the fifth transistor and having a gate connected to the output part.

13. The device of claim 12, wherein the switching element is brought to a non-conduction state when a voltage of the output part has a first logic level and is brought to a conduction state when a voltage of the output part has a second logic level.

14. The device of claim 9, wherein
assuming that a channel width and a channel length of the the fifth transistor are W5 and L5, respectively, a channel width and a channel length of the sixth transistor are W6 and L6, respectively, and a channel width and a channel length of the seventh transistor are W7 and L7, respectively, the voltage difference Vhys is determined by an expression 4 or an expression 12
Vhys=n×Vt×In(W5/L5+W6/L6)/(W7/L7)) Expression 4
Vhys=n×Vt×In((W5/L5+W7/L7)/(W6/L6)) Expression 12
(where n is a constant determined by a semiconductor manufacturing process and Vt is a thermal voltage).

15. The device of claim 1, wherein
the differential circuit comprises a first transistor provided on the first current path and receiving the first voltage at a gate thereof, and a second transistor provided on the second current path and receiving the second voltage at a gate thereof,
the second mirror circuit comprises a eighth transistor provided on the second current path, and a ninth transistor provided on the fourth current path, gates of the eighth and ninth transistors being connected to the second current path in common, and
the first circuit comprises a fifth transistor having a gate connected to the second current path, the fifth transistor being connected in parallel to the eighth or ninth transistor or disconnected from the eighth or ninth transistor according to a logic level of the output part.

16. The device of claim 15, wherein assuming that a channel width and a channel length of the fifth transistor are W5 and L5, respectively, a channel width and a channel length of the eighth transistor are W8 and L8, respectively, and a channel width and a channel length of the ninth transistor are W9 and L9, respectively, a voltage difference between the second voltage at a time when the output part is switched from a first logic level to a second logic level and the second voltage at a time when the output part is switched from the second logic level to the first logic level is determined based on a ratio between W5/L5+W8/L8 and W9/L9 or a ratio between W4/L4+W9/L9 and W8/L8.

17. The device of claim 15, wherein the first and second transistors operate in a weak inversion region.

18. The device of claim 15, wherein the first circuit further comprises a switching element connected in series with the fifth transistor and having a gate connected to the output part.

19. The device of claim 18, wherein the switching element is brought to a non-conduction state when a voltage of the output part has a first logic level and is brought to a conduction state when a voltage of the output part has a second logic level.

20. The device of claim 15, wherein
assuming that a channel width and a channel length of the fifth transistor are W5 and L5, respectively, a channel width and a channel length of the eighth transistor are W8 and L8, respectively, and a channel width and a channel length of the ninth transistor are W9 and L9, respectively, the voltage difference Vhys is determined by an expression 5 or an expression 13
Vhys=n×Vt×In((W3/L3+W9/L9)/(W8/L8)) Expression 5
Vhys=n×Vt×In((W4/L4+W8/L8)/(W9/L9)) Expression 13
(where n is a constant determined by a semiconductor manufacturing process and Vt is a thermal voltage).
